(19) United States
(12) Patent Application Publication
(10) Pub. No.: US 2022/0236079 A1
(43) Pub. Date: Jul. 28, 2022

(54) SYSTEMS AND METHODS FOR AUTOMATED METROLOGY

(71) Applicant: INNOVATIVE CANADIAN CAPITAL GROWTH INC., London (CA)

(72) Inventors: Bilal Rahhal, London (CA); Ali Hamou, London (CA); Belal Tassi, London (CA); Derek Chiu, Hamilton-Wentworth (CA); Jordan Hamilton, Peterborough (CA); Ron Pitman, Toronto (CA)

(21) Appl. No.: 17/616,498

(22) PCT Filed: Jun. 5, 2020
(86) PCT No.: PCT/CA2020/000066

§ 371 Date: Dec. 3, 2021

Related U.S. Application Data
(60) Provisional application No. 62/857,341, filed on Jun. 5, 2019.

(51) Int. Cl. G01D 4/00; G01R 22/06

(52) U.S. Cl. CPC G01D 4/002; G01D 2204/18; G01R 22/063

(57) ABSTRACT

An electric power meter comprising modules coupled to each other. The modules include a sealed measuring module, and a module different from the measuring module; and the modules configured to enable any module to be replaced independently of the measuring module. A method for an electric power meter including modules coupled to each other. The modules include a sealed measuring module, and a module different from the measuring module. The method includes configuring the modules to be replaced independently of the measuring module. A system for communications with multiple meters. The meters are coupled to a gateway via a network. Each of the meters communicates using one protocol. The network includes nodes coupled to the gateway. Each of the nodes corresponds to one of the protocols; and at least some of the meters is coupled to each of the nodes based on the protocol used by each of the meters.

### FIELD OF THE INVENTION

The present disclosure relates to metering equipment and technologies to communicate with various meters.

### BRIEF SUMMARY

An electric power meter comprising multiple modules coupled to each other, wherein the modules include a measuring module, and at least one module different from the measuring module. The modules are configured to enable the modules different from the measuring module to be replaced independently of the measuring module. The measuring module is preferably sealed. The modules different from the measuring module may be a communications module, power module, breaker module or others.

A method for an electric power meter having multiple modules coupled to each other, wherein the modules include a measuring module, and at least one module different from the measuring module. The method includes configuring the modules to enable the modules different from the measuring module to be replaced independently of the measuring module and to enable the measuring module to be replaced independently of the other modules.

A method for assembling an electric power meter comprising coupling multiple modules to each other, wherein the modules include a measuring module and at least one module different from the measuring module; and configuring the coupled modules to enable the modules different from the measuring module to be replaced independently of the measuring module and to enable the measuring module to be replaced independently of the other modules.

A method to acquire a network address for a power meter coupled to a gateway over a network, wherein a serial number is associated with the power meter, and the power meter includes a communications module. The method includes transmitting, by the communications module, a request to the power meter for the serial number; receiving, by the communications module, the serial number in response to the transmitted request; transmitting, by the communications module, the serial number to the gateway via the network; and transmitting, by the gateway and based on the transmission of the serial number, the network address to the power meter via the network.

A system for communications with multiple meters, wherein the meters are coupled to a gateway via a network, wherein each of the meters communicates using one of one or more protocols; the network includes multiple nodes coupled to the gateway, wherein each node corresponds to one of the one or more protocols; and at least some of the meters are coupled to each of the nodes based on the protocol used by each of the meters.

A method for autonomous self-configuration of multiple M-BUS meters including enabling, by a gateway coupled to the M-BUS meters, supply of power to the M-BUS meters; determining whether one or more M-BUS meters are newly added; based on the determining, requesting, by the gateway, an identifier from a first of the one or more newly added M-BUS meters; registering, by the gateway and based on receipt of the identifier, the first newly added M-BUS meter in a routing table; and setting up a schedule to poll the first newly added M-BUS meter for one or more readings.

A method for autonomous self-configuration for multiple meters utilizing PLC communications including establishing, by a gateway coupled to the meters, a network with the meters; determining whether one or more of the meters are waiting to communicatively couple to the gateway; based on the determining, requesting, by the gateway, an identifier from a first of the one or more meters waiting to communicatively couple to the gateway; transmitting a network address to the first meter; and registering the first meter in a routing table.

A system for a user device associated with a user, wherein the user device is coupled to a back-end system via a network, further wherein the back-end system comprises one or more back-end subsystems and a database; the user device includes a storage, a processor, a display, one or more input devices, a device communications unit, and one or more sensors; the system further including one or more applications stored on the storage, wherein the one or more applications include at least one of a mobile installation application, an energy consumption application, and an enterprise energy consumption application.

The foregoing and additional aspects and embodiments of the present disclosure will be apparent to those of ordinary skill in the art in view of the detailed description of various embodiments and/or aspects, which is made with reference to the drawings, a brief description of which is provided next.

### BRIEF DESCRIPTION OF THE DRAWINGS

The foregoing and other advantages of the disclosure will become apparent upon reading the following detailed description and upon reference to the drawings.

FIG. 1 illustrates an example embodiment of a modular power meter,

FIG. 2 illustrates an example process for acquisition of network addresses from a gateway.

FIG. 3A illustrates an example embodiment of a plurality of M-BUS meters.

FIG. 3B illustrates an example process for integrity checks of a plurality of M-BUS meters.

FIG. 4A illustrates an example embodiment of a plurality of meters coupled to a gateway with a scanning system.

FIG. 4B illustrates an example process for autonomous self-configuration of a plurality of M-BUS meters.

FIG. 4C illustrates an example process for autonomous self-configuration of a plurality of meters utilizing Power Line Communication (PLC) communications.

FIG. 5 illustrates an example embodiment of a plurality of meters coupled to a gateway via a plurality of nodes.

FIG. 6 illustrates an example embodiment of a user device associated with a user and coupled to a back-end system via a communications network.

FIG. 7A illustrates an example embodiment of a user device.

FIG. 7B illustrates examples of applications stored on the user device.

FIG. 8 illustrates an example embodiment of a back-end system.

FIG. 9 illustrates an example embodiment of an interface to obtain analysis results.

FIG. 10 illustrates an example embodiment of another interface to obtain analysis results.

FIG. 11 illustrates an example embodiment of yet another interface to obtain analysis results.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

Electric power meters are designed to measure electric power usage for various types of buildings and facilities, including but not limited to residential, commercial and industrial buildings and facilities such as apartment buildings, homes, condominium buildings, factories, offices, hospitals, hotels, retail buildings and so on. The following description details systems and methods for electric power meters.

Before use an electric power meter must be tested, sealed, commissioned then certified or verified. The cost and time needed to certify or verify an electric power meter is related to, among other things, the number of components which must be certified or verified. Prior art power meters are built in an integrated fashion, that is, where the components are integrated together within the power meter. In the case of failure of one component, the entire power meter must be installed, the seal must be broken, the defective component must be replaced, then the entire power meter must be recertified or reverified, resealed, recommissioned and reinstalled. The meter may be a gas meter, which have similar requirements to electrical power meters.

Designing and assembling the power meter in a modular fashion can provide savings of time and costs. In a modular power meter, each functional is performed by one or more modules. In some embodiments, these modules are physically separated from each other. If one of the modules needs to be removed and replaced with a new module, then in many cases that module can be replaced without requiring any resealing, recommissioning, recertification or reverification. This enables cost or time savings compared to the prior art case.

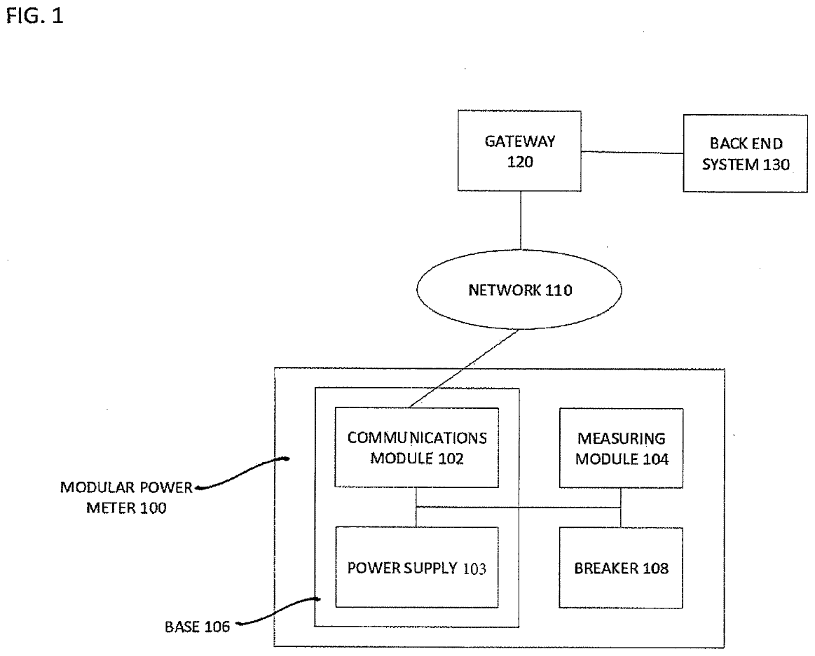

A system and method for a modular electric power meter or a modular power meter is described below. An example embodiment of a modular power meter is shown in FIG. 1. In some embodiments, modular power meter 100 is a modular single point power meter, which measures the power consumption of a single circuit within a single area of a residence. In other embodiments, the modular power meter 100 may be a multi-point power meter. Modular power meter 100 comprises modules such as measuring module 104, base 106 and breaker 108. Additionally, base 106 comprises communications module 102 and power supply 103. Communications module 102, power supply 103, measuring module 104, and breaker 108 are coupled to each other so as to enable communications and supply of power. In some embodiments, many of the modules, such as the power supply 103 or communication module are swappable.

The design and assembly of modular power meter 100 enables modules to seamlessly fit with each other to appear as a single compact unit to the end customer. Previously, end customers had to buy the various items from different suppliers, then buy a separate housing and put it together. This allows end customers to benefit from all the advantages of the module design, but also partake in the advantages of they are only dealing with one integrated system.

Measuring module 104 performs all the measurement functions within modular power meter 100. Many regulatory authorities around the world have strict regulations surrounding measuring module 104. For example, in Canada, Measurement Canada requires that measuring module 104 be sealed, commissioned, then certified or verified before operation. If measuring module 104 fails, then modular power meter 100 must be uninstalled, the seal must be broken, the defective module must be replaced, then the module must be resealed, recommissioned, recertified or reverified before the power meter 100 is reinstalled.

The modular design and assembly of meter 100 means that: If any of the modules different from measuring module 104 needs to be replaced, then that module can be replaced independently of measuring module 104. This means that modules different from measuring module 104 can be replaced without requiring any resealing, recommissioning and recertification or reverification. Thus, in many cases, this results in a substantial cost and time savings, as previously explained.

Modular power meter 100 is coupled to network 110 via communications module 102, and to gateway 120. In this specification, the terms “communications module” and “communications card” are used interchangeably. The communications module or communications card 102 facilitates communicative coupling between modular power meter 100 and network 110. In some embodiments, the communications card 102 only transmits data to the network 110 when it receives a request for data, which may be referred to as a “pull” communications mode. In some embodiments, the communications card 102 transmits data to the network 110 from its own volition, which may be referred to as a “push” communication mode.

In some embodiments, transmissions over the network 110 are in a first format, while the power meter 100 communicates using a second format. Then, communications card 102 translates or converts a communication in the first format and received from the network 110, into the second format for the power meter 100. This communication could comprise, for example, one or more requests for data from the power meter. In other embodiments, the communications card 102 translates or converts communications in the second format and originating from the power meter 100, into the first format for transmission over network 110. The conversion or translation functionalities of communications card 102 enable the power meter 100 to communicate over the network 110.

Network 110 is used to facilitate communications between the gateway 120 and meter 100. In some embodiments, network 110 is configured to facilitate communications using one or more technologies known to those of skill in the art. In network 110 various protocols, hardware and software are utilized. Protocols supported by network 110 may include, for example, PULSE, M-BUS, MODBUS, PLC (Powerline Communication), various types of radio frequency (RF) protocols (including various point-to-point protocols and various RF mesh protocols), and various types of). In some embodiments, at least some part of network 110 is formatted as a bus.

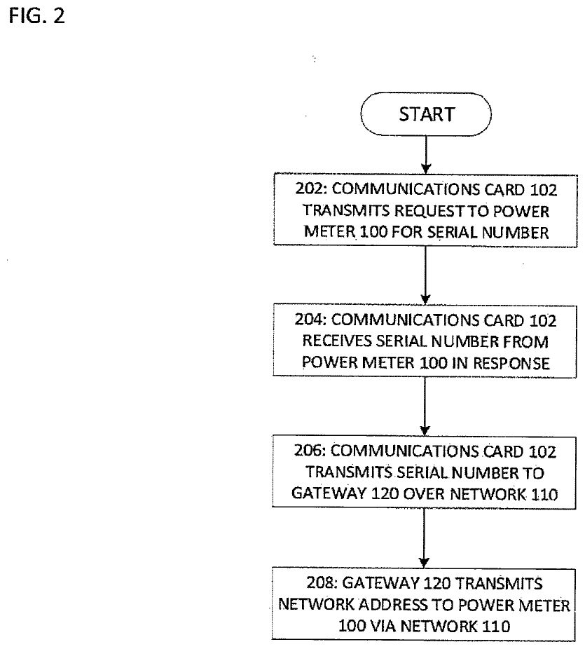

The communications card 102 also plays an important role in acquisition of network addresses from a gateway coupled to power meter 100 via network 110. An example process is shown with reference to FIGS. 1 and 2. In FIG. 2, in step 202 the communications card 102 transmits a request to the power meter 100 for the serial number of the power meter that the communications card is plugged into. In step 204, the communications card receives the serial number in response. In step 206, the communications card then transmits this serial number to the gateway 120 over network 110. In some embodiments, the serial number is hashed first and then transmitted. Finally, in step 208, based on the received transmission, the gateway 120 transmits a network address to power meter 100 via network 110.

In some embodiments, the communications card 102 indicates that it is receiving power and coupled to the network 110 using one or more light emitting diodes (LEDs). For example, the one or more LEDs are either turned on or flash when the communications card 102 is receiving power and is coupled to the network 110. In some embodiments, a first set of the one or more LEDs is used to indicate that the communications card 102 is receiving power, and a second set of the one or more LEDs is used to indicate that the communications card 102 is coupled to the network 110. In other embodiments, at least one of the one or more LEDs are located onboard the communications card 102.

In case of failure of the communications card 102, the modular design and assembly of the power meter 100 enables an appropriately certified or verified replacement communications card to be installed without needing to uninstall, unseal, re-certify or re-verify, reseal and reinstall the entire power meter 100. As explained previously, this enables cost and time savings. In some embodiments, to enable easy installation the communications card 102 is pluggable, that is, it has special connection arrangements so that a technician can rapidly plug and unplug the communications card 102, further reducing the time and cost needed to replace such a card.

The gateway 120 of FIG. 1 is capable of communicating with different types of meters, including, for example, gas meters, heat meters, water meters and so on. In further embodiments, gateway 120 also communicates with other types of electronic devices and sensors, including, for example, Internet of Things (IoT) devices and sensors. While only one power meter 100 is shown coupled to gateway 120 in FIG. 1, in some embodiments, a plurality of peers comprising meters, devices and sensors are coupled to gateway 120 via network 110. These embodiments will be illustrated further below.

In some embodiments, gateway 120 establishes network 110. In these embodiments, gateway 120 designates itself as a coordinator, then sends out a beacon signal to meters, sensors and devices that are physically coupled to gateway 120. In some embodiments, multiple gateways may exist within the network. In this situation each of the gateways can be designated by the peer as its coordinator and relay multiple beacons to the meters, sensors, and devices that are physically coupled to it.

In some embodiments, gateway 120 enables supply of power to all the meters, sensors and devices that are physically coupled to gateway 120.

In some embodiments, gateway 120 polls the meters, sensors and devices which are coupled to gateway 120 via network 110 to obtain readings from the meters, sensors and devices.

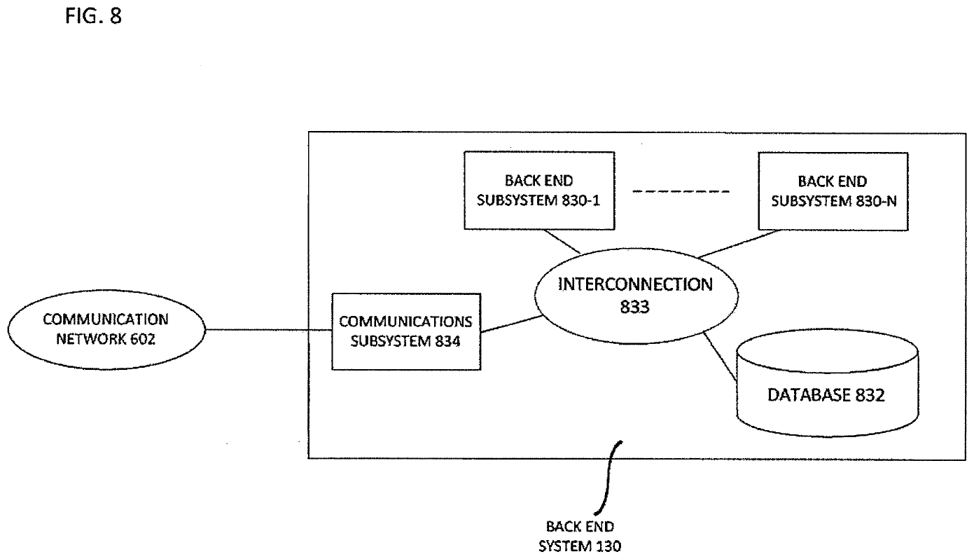

Back-end system 130 is discussed and described in further detail below and in FIG. 8.

The M-BUS technology allows for provision of both communications and power to meters. For the embodiments where the gateway communicates with meters using M-BUS, it is important to realize that prior art M-BUS systems lacked adequate integrity checking functionalities. In this specification a system and method for integrity checking for M-BUS meters is detailed below.

An integrity check is performed automatically by the gateway 120 to determine if there are looped connections, broken wires or other faults. This allows for safer operation when compared to prior art M-BUS systems. It can also protect all the meters, which can reduce cost and time when a meter breaks down.

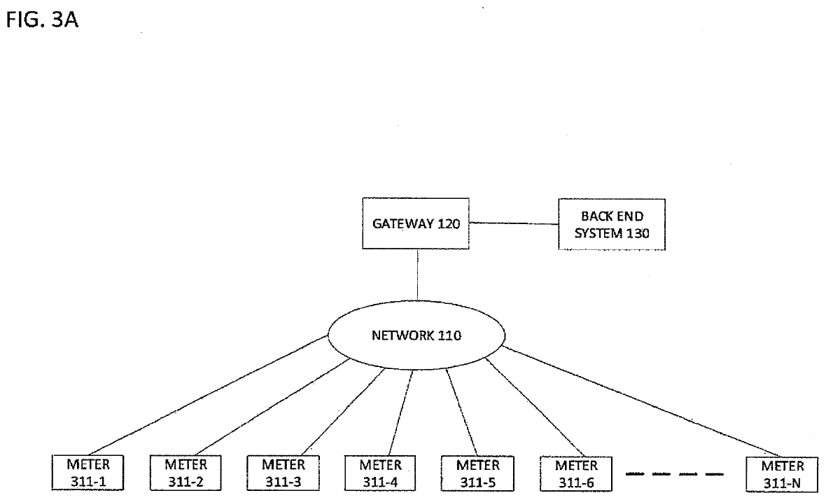

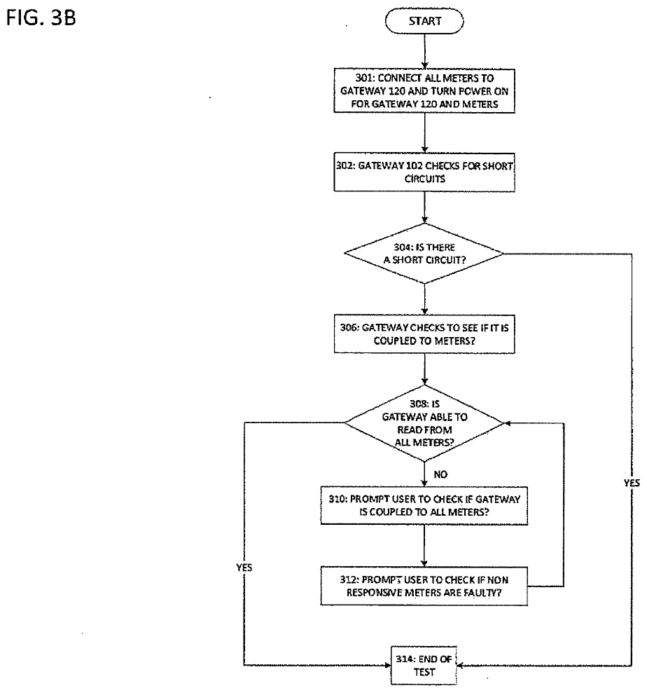

An example of a process for integrity checks is detailed with reference to FIGS. 3A and 3B. In FIG. 3A, gateway 120 is coupled to plurality of M-BUS meters 311-1 to 311-N via network 110. Gateway 120 is also coupled to back end system 130. FIG. 3B details the process for integrity checks. In step 301, all meters are connected to gateway 120, and power for gateway 120 and all meters is turned on. In step 302, the gateway 120 checks for short circuits. If a short circuit is detected in step 304, then the test is ended at step 314. However if no short circuit is detected, then in step 306 the gateway checks to see if it is properly coupled to all meters. If it is able to read from all meters then the test ends at step 314. If not, then in step 310 the user is prompted to check if the gateway 120 is coupled to all meters, and in step 312 the user is prompted to check if non responsive meters are faulty. In some embodiments, in step 312 the user is prompted to check for a faulty meter by first connecting a fully functional meter and then attaching a suspected faulty meter.

Prior art M-BUS systems required extensive manual configuration. This was time-consuming, as for each device there was a need to understand the protocol in operation. There is a need for an M-BUS system with autonomous self-configuration, and which therefore does not require the extensive manual configuration found in prior art M-BUS systems. Such a system would have reduced time and costs when compared to the prior art systems.

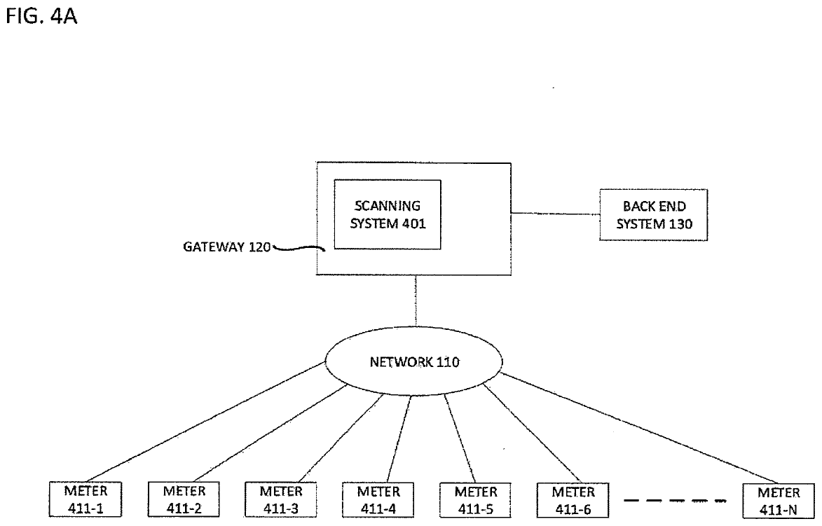

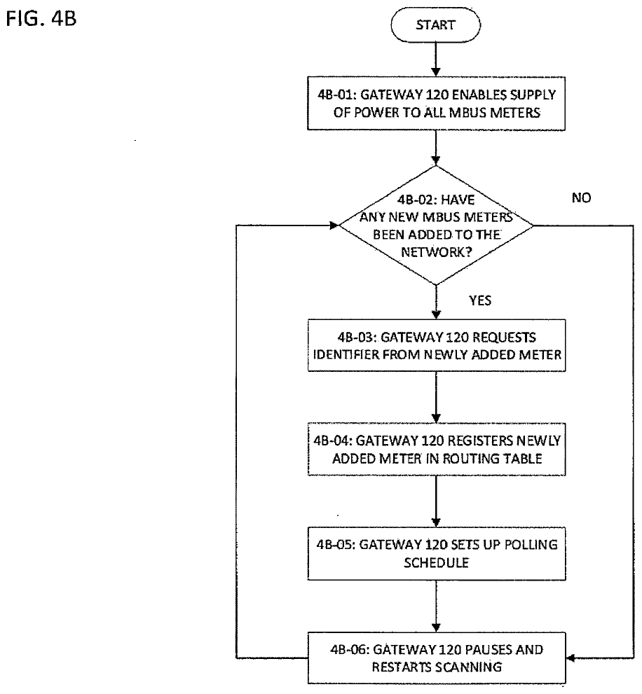

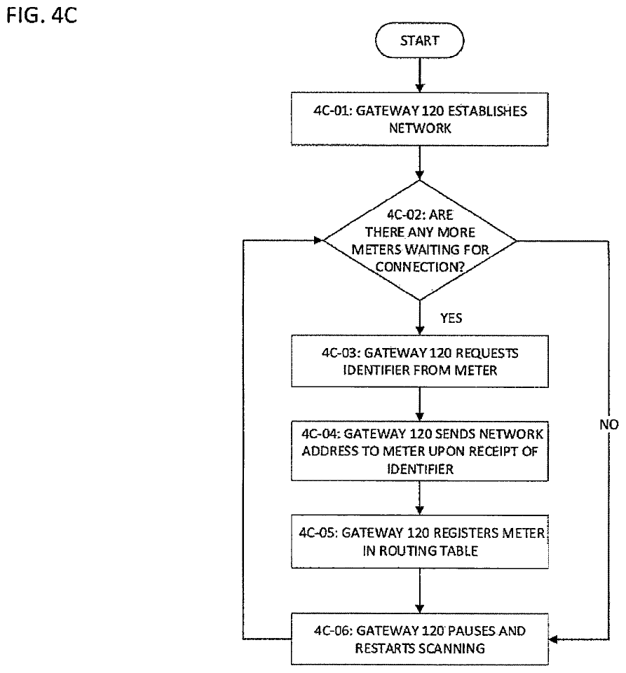

An example embodiment of an M-BUS system with autonomous self-configuration is demonstrated with reference to FIGS. 4A and 4B.

In FIG. 4A, similar to FIG. 3A gateway 120 is coupled to plurality of meters 411-1 to 411-N via network 110. Additionally, gateway 120 in FIG. 4A comprises scanning system 401. Gateway 120 is also coupled to back end system 130.

For the purposes of the discussion below, meters 411-1 to 411-N are M-BUS meters. Then FIG. 4B shows an example flowchart for an autonomous self-configuration process for these M-BUS meters. In step 4B-01, as described previously, gateway 120 enables supply of power to meters 411-1 to 411-N. In step 4B-02 scanning system 401 on gateway 120 scans to determine whether the meters 411-1 to 411-N comprise M-BUS meters which have been newly added to the network 110. If no, then the process moves to step 4B-06, where scanning system 401 on gateway 120 pauses and restarts scanning. If yes, then in step 4B-03, scanning system 401 on gateway 120 requests an identifier from the newly added M-BUS meter. In step 4B-04, upon receipt of the identifier, scanning system 401 on gateway 120 registers the newly added meter in a routing table. In step 4B-05, scanning system 401 on gateway 120 sets up a schedule to poll the newly added meter for readings. In step 413-06 scanning system 401 on gateway 120 pauses and restarts the scanning process. In this manner, any new M-BUS meters which have been added to the network 110 can be connected.

When the scanning system 401 receives new data from a newly added M-BUS meter, then in some embodiments it adds the new data to previously compiled data or reports. Scanning system 401 then communicates information based on this newly received data to the back-end system 130.

Similarly, prior art Power Line Communication (PLC) systems required extensive manual configuration and suffered from the same disadvantages as the prior art M-BUS systems. There is a need for an autonomous self-configuration system for use with meters which utilize PLC communications. Such a system is described with reference to FIGS. 4A and 4C. For the purposes of the discussion below, meters 411-1 to 411-N utilize G3-PLC communications. In step 4C-01, as described previously, gateway 120 establishes network 110. This comprises gateway 120 designating itself as a coordinator, then sending out a beacon signal to meters 411-1 to 411-N. In step 4C-02, gateway 120 scans to see if there are any meters waiting to communicatively couple with gateway 120. If no, then the process moves to step 4C-03, where gateway 120 pauses and restarts scanning. If yes, then in the gateway 120 requests an identifier from the meter that is waiting to connect. In step 4C-04, upon receipt of the identifier, gateway 120 transmits a network address to the meter waiting to connect. In step 4C-05, gateway 120 registers the meter in a routing table. The process moves to step 4C-06, where gateway 120 pauses and restarts scanning. While the above has been described for meters, one of skill in the art would understand that it is applicable to other devices, sensors or nodes.

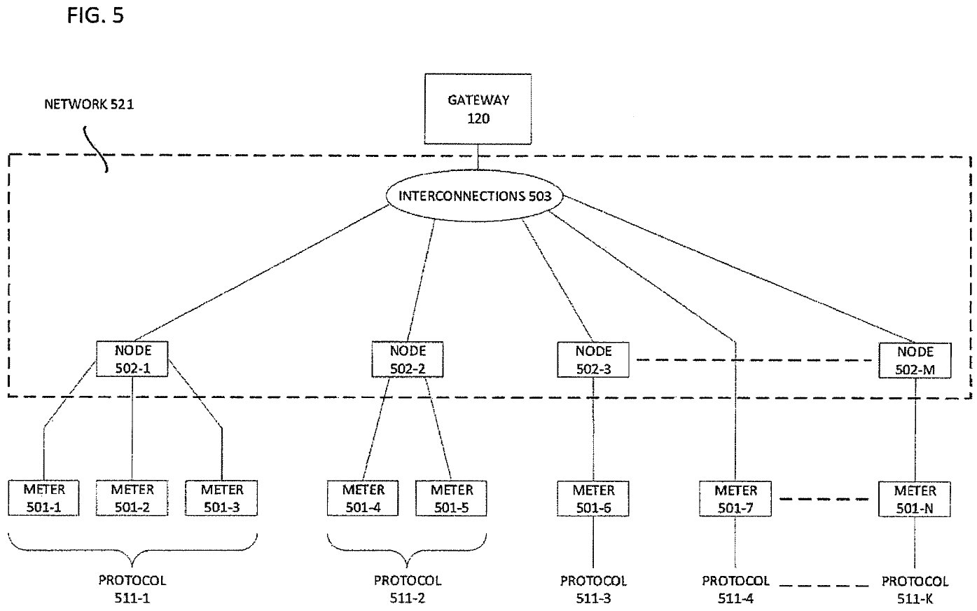

Prior art gateway systems could only communicate using a limited number of protocols, which limited their abilities to communicate with different types of meters. This specification details a system and method for a gateway to communicate with meters by dynamically expanding its number and types of network protocols through the addition of each new communication node. FIG. 5 shows an example of such a system and method.

In FIG. 5, network 521 plays a similar role to network 110, that is, network 521 couples gateway 120 to meters 501-1 to 501-N. Meters 501-1 to 501-N communicate using one or more protocols such as PULSE, M-BUS, MODBUS, PLC, and various RF technologies and other technologies known to those of skill in the art.

Network 521 of FIG. 5 additionally comprises nodes 502-1 to 502-M and interconnections 503. Nodes 502-1 to 502-M act as intermediaries between gateway 120 and meters 501-1 to 501-N. As shown in FIG. 5, nodes 502-1 to 502-M are coupled to gateway 120 via interconnections 503. Each of nodes 502-1 to 502-M corresponds to one of protocols 511-1 to 511-K and is coupled to one or more meters which use that protocol for communication. For example, meters 501-1 to 501-3 communicate using protocol 511-1. Then, node 502-1 acts an intermediary for meters 501-1 to 501-3 and gateway 120. That is, node 502-1 couples gateway 120 to these meters and acts to translate communications directed to these meters and received from the gateway 120 into protocol 511-1 for these meters. Similarly, meters 501-4 and 501-5 communicate using protocol 511-2, and node 502-2 acts as an intermediary for these meters and gateway 120.

In some embodiments, at least one of meters 501-1 to 501-N is coupled to gateway 120 without being coupled to a node. For example, with reference to FIG. 5, meter 501-7 communicates using protocol 511-4 and couples to gateway 120 via interconnections 503, but unlike meters 501-1 to 501-6, meter 501-7 is not coupled to a node.

Nodes 502-1 to 502-M act to extend the capabilities and range of gateway 120 to communicate using a variety of protocols. For example, gateway 120 may not be able to communicate with all the meters 501-1 to 501-N as it may not have the capabilities to communicate according the protocols used by meters 501-1 to 501-N. Then, nodes 502-1 to 502-M allow for the gateway 120 to communicate with the meters.

Additionally, in some embodiments, at least one of nodes 502-1 to 502-M acts to extend the range of gateway 120 to communicate with meters 501-1 to 501-N. For example, in FIG. 5 meter 501-6 is outside the communications range of gateway 120. However, node 502-3 acts to extend the range of gateway 120 to enable communications with meter 501-6.

As explained previously, nodes 502-1 to 502-M are coupled to gateway 120 via interconnections 503. In some embodiments, nodes 502-1 to 502-M are powered from an independent power supply or from the gateway 120 via interconnections 503. Interconnection 503 provides communicative coupling between gateway 120 and node 502. In some embodiments, this is performed using PLC or RF technologies. In some embodiments, interconnections 503 is facilitated by having the node 502 directly plug into the gateway.

In some embodiments, a combination of the gateway 120 and at least one of the nodes 502-1 to 502-M are remotely programmable. This enables, for example, updating to extend the capabilities of the nodes 502-1 to 502-M.

In yet other embodiments, for each gateway such as gateway 120 that is employed, there is a redundant gateway set up. In some embodiments, this redundancy comprises mirroring the gateway. In some embodiments, the redundant gateway is set up to autonomously take over the operation of the employed gateway in case of failure. Providing this redundancy improves resilience to failure.

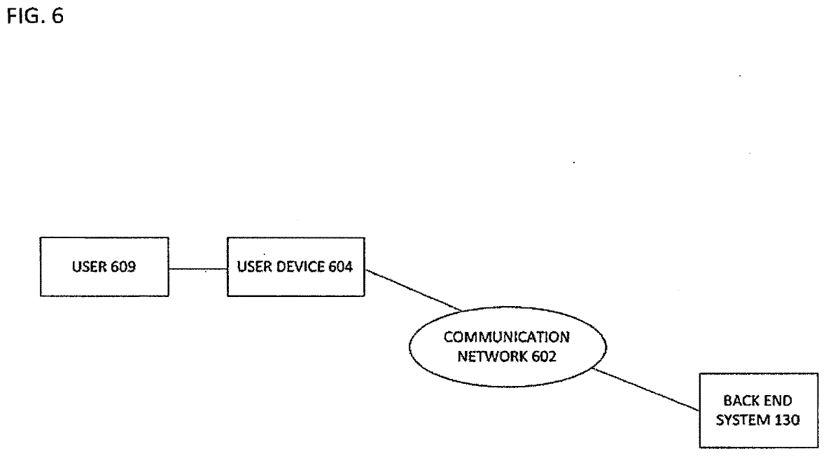

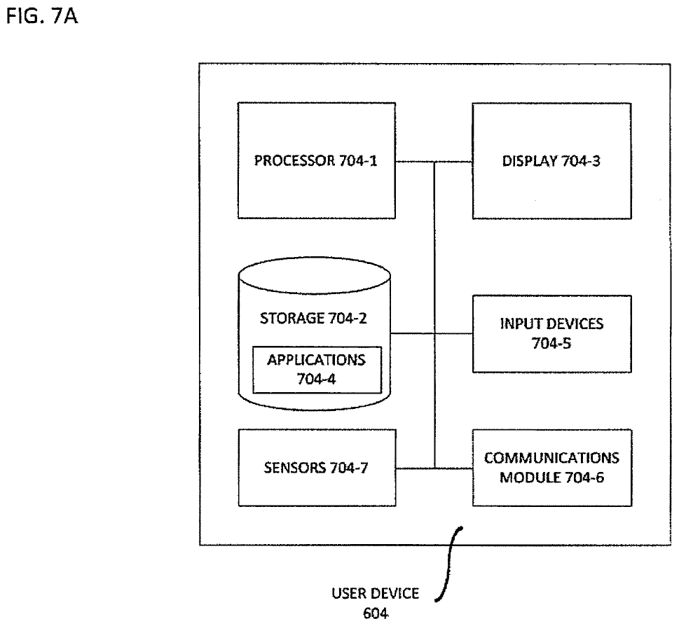

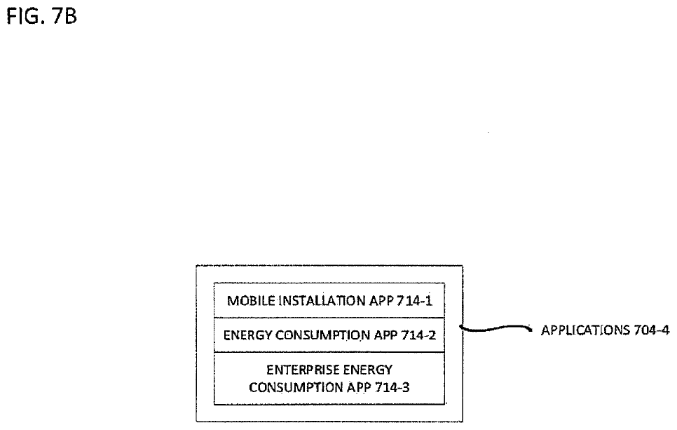

Additionally, several different application or “apps” are provided for user devices to interact with back end system 130 and provide data of interest to users associated with the user devices. An example is shown in FIGS. 6 and 7. In FIG. 6, user device 604 is associated with user 609 and coupled to back end system 130 via communications network 602.

User device 604 is, for example a smartwatch, smartphone, tablet, laptop, or any appropriate computing and network-enabled device. An embodiment of user device 604 is shown in FIG. 7A. Processor 704-1 performs processing functions and operations necessary for the operation of mobile device 704, using data and programs stored in storage 704-2.

Examples of the programs stored in 704-2 are applications or “apps” 704-4. Some examples of apps 704-4 are shown in FIG. 7B. These include, for example mobile device installation application 714-1, energy consumption app 714-2 and enterprise energy consumption app 714-3. These applications will be described further below.

Display 704-3 of FIG. 7A performs the function of displaying data and information for user 609. Input devices 704-5 allow user 609 to enter information. This includes, for example, devices such as a touch screen, mouse, keypad, keyboard, microphone, camera, video camera and so on. In one embodiment, display 704-3 is a touchscreen which means it is also part of input devices 704-5. Device communications unit 704-6 allows user device 704 to communicate with devices and networks external to mobile device 704 such as communication network 602. This includes, for example, wired or wireless communications via protocols and technologies such as BLUETOOTH®, Wi-Fi, Near Field Communications (NFC), Radio Frequency Identification (RFID), 3G, Long Term Evolution. (LTE), Universal. Serial Bus (USB) and other protocols and technologies known to those of skill in the art. Sensors 704-7 perform functions to sense or detect environmental or locational parameters. Sensors 704-7 include, for example, accelerometers, gyroscopes, magnetometers, barometers, Global Positioning System (GPS), proximity sensors and ambient light sensors. The components of mobile device 704 are coupled to each other as shown in FIG. 7.

Communications network 602 of FIG. 6 may be implemented in a variety of ways. For example, in some embodiments, communications network 602 comprises one or more subnetworks. In another embodiment, communications network 602 is implemented using one or more types of networks known to those of skill in the art. These types of networks include, for example, wireless networks, wired networks, Ethernet networks, personal area networks (PAN), local area networks (LANs), metropolitan area networks (MAN), wide area networks (WAN), data cellular networks and optical networks. In some embodiments, communications network 602 comprises at least one of a private or a public network.

An example embodiment of back end system 130 of FIG. 6 is described in further detail in FIG. 8. As shown in FIG. 8 back end system 130 comprises communications subsystem 834, database 832 and one or more back end subsystems 830-1 to 830-N.

Communications subsystem 834 is coupled to communication network 602. Communications subsystem 834 receives information from, and transmits information to communication network 602.

Back-end subsystems 830-1 to 830-N further comprise one or more subsystems such as:
Billing management subsystems,
Reporting subsystems,
Information management and data analytic subsystems,
Asset and inventory management subsystems,
Workflow management subsystems,
Artificial Intelligence (AI) and knowledge management subsystems,
Device management and control subsystems,
Event and operations alerting management subsystems, and
Testing subsystems.

Database 832 stores information and data for use by back-end system 130. This comprises, for example
meter states obtained from, for example, meter 100 of FIG. 1 and meters 411-1 to 411-N of FIG. 4A;
gateway states;
raw meter reads from, for example meter 100 of FIG. 1 and meters 411-1 to 411-N of FIG. 4A,
formatted types;
all types of sensor information;
communication information and states;
all meta-data associated with meter and sensor reads;
meter statuses obtained from, for example meter 100 of FIG. 1 and meters 411-1 to 411-N of FIG. 4A; and
other diagnostic information.

In one embodiment, database 832 further comprises a database server. The database server receives one or more commands from, for example, back end subsystems 830-1 to 830-N and communication subsystem 834, and translates these commands into appropriate database language commands to retrieve and store data into database 832. In one embodiment, database 832 is implemented using one or more database languages known to those of skill in the art, including, for example, Structured Query Language (SQL). In a further embodiment, database 832 stores data for a plurality of users. Then, there may be a need to keep the set of data related to each user separate from the data relating to the other users. In some embodiments, database 832 is partitioned so that data related to each user is separate from the other users. In some embodiments, each user has an account with a login and a password or other appropriate security measures to ensure that they are only able to access their data, and unauthorized access of their data is prohibited. In a further embodiment, when data is entered into database 832, associated metadata is added so as to make it more easily searchable. In a further embodiment, the associated metadata comprises one or more tags. In yet another embodiment, database 832 presents an interface to enable the entering of search queries. In some embodiments, the data stored within database 832 is encrypted for security reasons. In further embodiments, other privacy-enhancing data security techniques are employed to protect database 832.

Applications or “apps” 704-4 are now discussed in further detail with respect to FIGS. 6, 7A, 7B and 8. There is a need to track where meters are in a high-rise building. In some further embodiments, as shown in FIG. 7B, apps 704-4 comprise a mobile installation app 714-1 to detect the position of a meter in a building. In some of these embodiments, a Quick Response (QR) code is attached to the meter. Then using, for example, an image capture device which is part of input devices 704-5 in user device 604, an image of the meter and the QR code is captured by mobile installation app 714-1 and transmitted to back end system 130 over communication network 602 to be stored in database 832. In some embodiments, data captured by sensors 704-7 are also captured by mobile installation app 714-1 and transmitted to back end system 130. Using a combination of one or more of the stored QR code and the data captured by sensors 704-7, an altitude is estimated using one or more calculations performed by one or more of back end subsystems 830-1 to 830-N. Based on this estimated altitude, the position of the meter is calculated by one or more of back end subsystems 830-1 to 830-N.

In some embodiments, as shown in FIG. 7B, apps 704-4 comprise an energy consumption app 714-2. In these embodiments, user 609 of FIG. 6 is a resident in an apartment building or a condominium building. Data is captured using, for example, meters 501-1 to 501-N of FIG. 5 located in the rental apartments or condominium buildings, or meter 100 of FIG. 1 and transmitted to back end system 130 to be stored in database 832.

Then, user 609 uses the energy consumption app 714-2 to interact with back end system 130 to obtain different types of analyses. In particular, in some embodiments, energy consumption app 714-2 interacts with one or more of back end subsystems 830-1 to 830-N in back end system 130 to obtain the different types of analyses.

In some embodiments, the energy consumption app 714-2 interacts with one or more of back end subsystems 830-1 to 830-N in back end system 130 to obtain temporal analyses, which are analyses of user 609 energy consumption over one or more periods of time.

In some embodiments, the temporal analyses comprise intra-temporal analyses, which are analyses of energy usage by user 609 within a period. For example, these intra-temporal analyses comprise analyses of energy usage within one or more sub-periods within a period, which includes, for example:
Energy consumption in one or more hours within a day, or
Energy consumption in one or more days within a month.

These intra-temporal analyses also comprise, for example, analysis of proportion of energy usage during sub-periods where energy prices are at their peak as compared to other periods. An example analysis is as follows:
A different consumption rating is assigned to each of the sub-periods which make up a period, based on, for example the cost of energy during the sub-period:
   a “peak” rating is assigned to the period of 4-5 pm, as a utility company's per kilowatt-hour (kWh) charges are the highest during this period;
   a “medium” rating is assigned to the period of 10-11 am, as the utility company's per kWh charges are the next highest during this period; and
   an “off-peak” rating is assigned to the period of 1-2 am, as the utility company's per kWh charges are the lowest during this period.

Then based on this assignment, one or more analyses can be performed, for example:
Determination of proportion of a resident's energy consumption during a period which occurs during one or more peak sub-periods as compared to non-peak periods.

In some embodiments, the temporal analyses comprise inter-temporal analyses, which are one or more analyses of energy usage for a user 609 for a period as compared to one or more other periods. Examples of inter-temporal analyses would be:
How does a resident's energy usage vary from day to day?
How does a resident's proportion of energy usage vary from day to day?

In some embodiments, the energy consumption app 714-2 interacts with back end system 130 to obtain inter-resident analyses, which are analyses of energy consumption among residents. Example analyses include:
Comparison and ranking of daily energy usage among residents, and
Comparison and ranking of proportion of daily energy usage among residents.
Comparison and ranking of total building energy usage among similar buildings

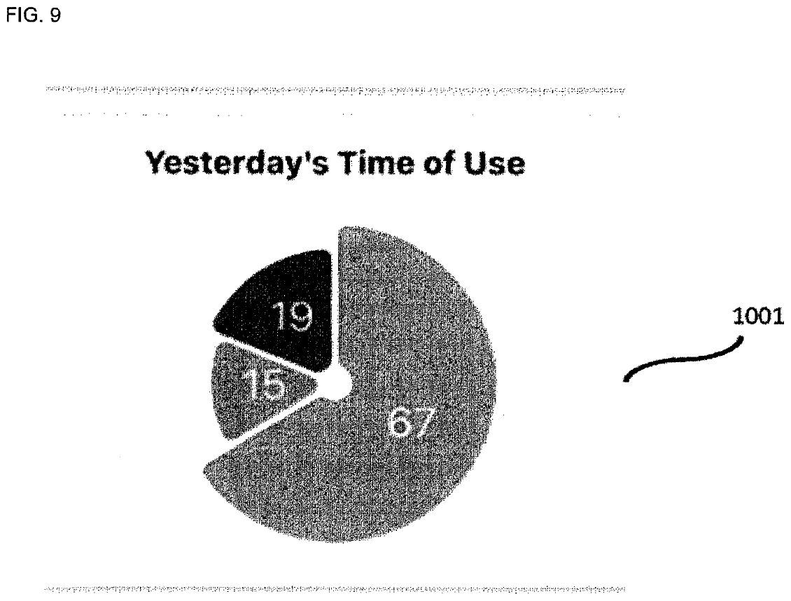

In some embodiments, these analyses are obtained by user 609 interacting with user device 604 via input devices 704-5 and using interfaces presented by the energy consumption app 714-2, so as to enable the analyses to be performed by back-end system 130. Example screens are shown in FIGS. 9-11.

The user 609 is able to login to their account via entering, for example, a username and a password using input devices 704-5. The user name is, for example, an email address, telephone number or a string of characters and/or numbers. As explained previously this information is also stored in database 832. When the user enters a username and a password, the entered information is cross referenced against the information stored in database 832.

User 609 can obtain analyses using various interfaces. An example is presented in FIG. 9. In FIG. 9, the user 609 interacts with interface 1001 using, for example, input devices 704-5 to obtain a proportion of the user's energy consumption during one or more peak sub-periods as compared to medium and non-peak sub-periods. The analysis is performed by, for example, one or more of back-end subsystems 830-1 to 830-N using data stored in database 832. For example, in FIG. 9, interface 1001 shows that 67% of the user's energy consumption occurred during non-peak sub-periods, 19% occurred during peak sub-periods, and 15% of the user's energy consumption occurred during medium usage sub-periods.

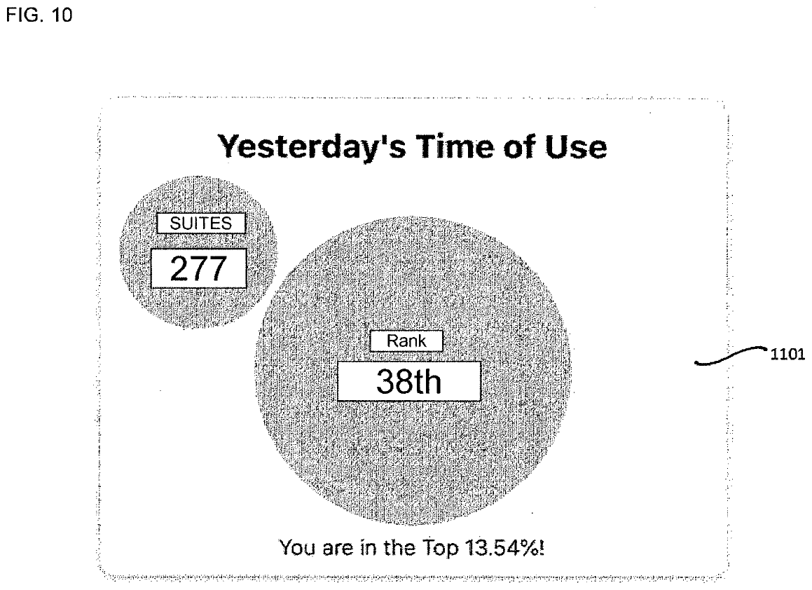

User 609 is able to obtain a ranking of user 609 compared to other users by interacting with interface 1001. The ranking is performed by, for example, one or more of back-end subsystems 830-1 to 830-N using data stored in database 832. Interface 1101 of FIG. 10 presents the result of the ranking. From interface 1101, it can be seen that user 609 ranks 38th among the residents in the building that user 609 lives in. This ranking algorithm can factor in many elements—such as Time of Use (TOU), intensity and duration of sustained usage etc.—and hence is quite sophisticated.

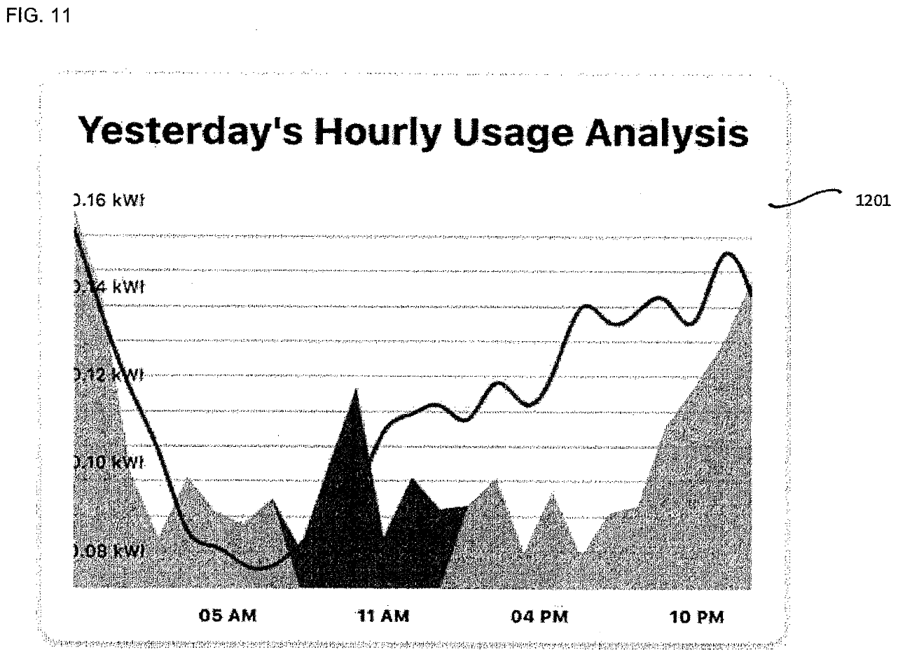

User 609 is also able to view hourly usage within a given day. An example interface 1201 is presented in FIG. 11.

In some embodiments, as shown in FIG. 7B, apps 704-4 comprise an enterprise energy consumption app 714-3 for use by a company owning a plurality of properties so as to perform temporal, inter-property analyses and intra-property analyses which are similar to those explained above. The user 609 in this case is, for example, a member of staff of the company.

In a further embodiment, the meter lifecycle process is automated. This involves performing periodic testing and analyses of results from the testing so as to determine how the performance of a meter evolves over its lifetime, and results in a huge improvement in the quality and reduces the error rate of meters.

Beyond the advantages discussed above, the invention also provides the following advantages.

The small communication nodes utilized in this system, facilitate the ability for the gateway to communicate universally to any type of protocol and hence any type of meter, sensor, or IoT end-device. This means that end-devices, such as smart meters, or simple meters and sensors, can be of different models and types, each supporting different protocols, on the same network, coordinated by one gateway. These nodes can be added dynamically at any time, possibly expanding the existing communication protocols found on the network each time.

When added, the nodes detect the closest coordinating gateway on the network, and the end-device they are connected to leveraging the available direct connection interface on the end device such as RS-485, pulse, or other interfaces.

The nodes enable two-way communication with the end-device and the gateway network. Each node device understandings and translates between at least two protocols: one on the device side and one on the gateway/network side. The nodes are not limited to a specific type or brand of meter or device, but instead can speak to any device using the protocols it supports. Many different nodes are built to support the numerous communication protocols utilized by meters, sensors and other IoT devices.

In prior solutions, devices have been attached to smart meters to have this new device act as a stand-in for the meter itself (henceforth referred to as a “virtual meter”). Other entities in the system would then interface directly with this virtual meter, instead of the smart meter itself, which continues to perform its functions behind the virtual meter—and interacts only with it one-to-one.

In contrast, in this system nodes act as a true bridge between any end-device, such as a smart meter or sensor, and the building gateway network. The node is built with two terminal interfaces provided to each side of the bridge to permit communication between the devices and the gateway network.

Nodes are plug and play within the system network. This bridge approach is one of the factors that enable the node to not require any configuration when paired to a new end-device, such as an electrical smart meter or water quality sensor. This is in contrast to the virtual meter type approaches which often require extensive configuration when attached.

Once a node is installed—it configures itself and informs the user via means of LED lighting, that it has connected to the end-device (meter, sensor, etc.) on one channel and connected to the gateway coordinator on the other channel (and through this entire network). The gateway then self-configures the data, reporting, security and other important factors on the node and end-device based on the policies and the type of end device connected. Manual configuration is not required except for the simplest of devices (such as a PULSE counter) which cannot provide anything piece of information—and even then, only a single item, a name labelling the end device, is needed by the back-end system.

Nodes are data pass-through communication devices, and are not data collection devices such as the gateways or DCU (Data Concentrator Unit). It is the gateway that determines the packet information decoding. Nodes do not permanently store any data request from either the gateway it is coordinating with or the end-device it is facilitating communication for. Instead, all information is passed through the nodes, or temporarily cached as part of this pass through.

Nodes act as acts as an intermediary without interpretation of the data it is streaming. This is what enables true universality with any end-device. This provides seamless bridging of end devices into the network and enables the end-devices, such as smart meters, to send and receive its data and be able to interact directly with other authorized entities on the network. This facilitates the meters or sensor end-devices to be completely integrated into the network without needing to interact with an intermediary.

In this system, the centralized active actor that facilitates all intelligence and data collection on the network are the Gateways. The gateway determines the packet information decoding, facilitates all communication and requests from the back-end systems, secures the network, and facilitates all communication with the end-devices, sometimes through nodes devices and sometimes directly connected to the meter (both setups are supported on the same network). Algorithms for pulling of data and pushing of data to any device on the network is initiated by the gateway on the network. Nodes respond to the intelligence and can enact network policies by the gateway, however do not ever autonomously do this without the coordination of the active gateway. Gateways can leverage the back end to enhance their network understanding, or enact independent decisions based on their inherent algorithmic sets.

Alternative prior solutions allow the communication devices to be plugged into an electrical socket and provide an electrical plug integrated into the device to replace the used socket. In our solution, all PLC gateways and node devices are hardwired into a buildings power system. This both protects the network from end users removing power to these critical communication devices enabling the network or the danger to unsuspecting users from shorting hazardous power systems. This is especially important when the devices are installed inside of occupied residential suites.

Although the algorithms described above including those with reference to the foregoing flow charts have been described separately, it should be understood that any two or more of the algorithms disclosed herein can be combined in any combination. Any of the methods, algorithms, implementations, or procedures described herein can include machine-readable instructions for execution by: (a) a processor, (b) a controller, and/or (c) any other suitable processing device. Any algorithm, software, or method disclosed herein can be embodied in software stored on a non-transitory tangible medium such as, for example, a flash memory, a CD-ROM, a floppy disk, a hard drive, a digital versatile disk (DVD), or other memory devices, but persons of ordinary skill in the art will readily appreciate that the entire algorithm and/or parts thereof could alternatively be executed by a device other than a controller and/or embodied in firmware or dedicated hardware in a well-known manner (e.g., it may be implemented by an application specific integrated circuit (ASIC), a programmable logic device (PLD), a field programmable logic device (FPLD), discrete logic, etc.). Also, some or all of the machine-readable instructions represented in any flowchart depicted herein can be implemented manually as opposed to automatically by a controller, processor, or similar computing device or machine. Further, although specific algorithms are described with reference to flowcharts depicted herein, persons of ordinary skill in the art will readily appreciate that many other methods of implementing the example machine readable instructions may alternatively be used. For example, the order of execution of the blocks may be changed, and/or some of the blocks described may be changed, eliminated, or combined.

It should be noted that the algorithms illustrated and discussed herein as having various modules which perform particular functions and interact with one another. It should be understood that these modules are merely segregated based on their function for the sake of description and represent computer hardware and/or executable software code which is stored on a computer-readable medium for execution on appropriate computing hardware. The various functions of the different modules and units can be combined or segregated as hardware and/or software stored on a non-transitory computer-readable medium as above as modules in any manner, and can be used separately or in combination.

While particular implementations and applications of the present disclosure have been illustrated and described, it is to be understood that the present disclosure is not limited to the precise construction and compositions disclosed herein and that various modifications, changes, and variations can be apparent from the foregoing descriptions without departing from the spirit and scope of an invention as defined in the appended claims.

1. An electric power meter comprising a plurality of modules coupled to each other, wherein:
the plurality of modules comprises a sealed measuring module, and at least one module different from the measuring module; and
said plurality of modules configured to enable the modules different from the measuring module to be replaced independently of the measuring module.

2. The power meter of claim 1, wherein
the power meter further comprises a communications mule module, and the power meter is coupled to a network via the communications module, wherein the communications module facilitates communicative coupling between the power meter and the network wherein:
the communication module receives a communication from the network in a first format; and
the communications module converts the communication from the first format into a second format for use by the power meter

3. The power meter of claim 2, wherein the communications module transmits data to the network only when the communications module receives a request for the data.

4. The power meter of claim 2, wherein:
the power meter is coupled to a gateway over the network;
a serial number is associated with the power meter;
the communications module transmits a request to the power meter for the serial number; the communications module receives the serial number in response to the transmitted request;
the communications module transmits the serial number to the gateway via the network; and
based on the transmission of the serial number, the gateway transmits a network address to the power meter via the network.

5. A method for an electric power meter comprising a plurality of modules coupled to each other, wherein
the plurality of modules comprises a measuring module, and at least one module different from the measuring module,
said method comprising configuring the plurality of modules to enable the modules different from the measuring module to be replaced independently of the measuring module.

6. A method to acquire a network address for the power meter of claim 1 coupled to a gateway over a network, wherein
a serial number is associated with the power meter, and
the power meter comprises a communications module;
the method comprising:
transmitting, by the communications module, a request to the power meter for the serial number;
receiving, by the communications module, the serial number in response to the transmitted request;
transmitting, by the communications module, the serial number to the gateway via the network; and
transmitting, by the gateway and based on the transmission of the serial number, the network address to the power meter via the network.

7. A system for communications with a plurality of the power meter of claim 1, wherein:
the plurality of power meters is coupled to a gateway via a network, wherein each of the plurality of meters communicates using one of one or more protocols;
the network comprises a plurality of nodes coupled to the gateway, wherein each of said plurality of nodes corresponds to one of the one or more protocols; and
at least some of the plurality of power meters are coupled to each of the plurality of nodes based on the protocol used by each of the at least some of the plurality of power meters.

8. The system of claim 7, wherein:
the gateway transmits communications directed to a first of the plurality of power meters;
a first of the plurality of nodes coupled to the first power meter receives the transmitted communications; and
the first node translates the received communications into the protocol used by the first power meter for communications.

9. The system of claim 7, wherein at least one of the plurality of nodes extends a communication range of the gateway.

10. (canceled)

11. A method for autonomous self-configuration for a plurality of meters utilizing PLC communications comprising:
establishing, by a gateway coupled to the plurality of meters, a network with the plurality of meters;
determining whether one or more of the meters are waiting to communicatively couple to the gateway;
based on the determining, requesting, by the gateway, an identifier from a first of the one or more meters waiting to communicatively couple to the gateway;
transmitting a network address to the first meter; and
registering the first meter in a routing table.

12. A system for a user device associated with a user, wherein
said user device is coupled to a back-end system via a network, further wherein
the back-end system comprises one or more back-end subsystems and a database, said user device comprises
a storage,
a processor, a display,
one or more input devices,
a device communications unit, and
one or more sensors;
the system further comprising one or more applications stored on said storage, wherein the one or more applications comprise at least one of
a mobile installation application,
art energy consumption application, and
an enterprise energy consumption application.

13. The system of claim 12, wherein the mobile installation application is used to provide data to the one or more back end subsystems to enable a position of a meter to be calculated.

14. The system of claim 12, wherein the energy consumption application is used to interact with the one or more back end subsystems to obtain one or more analyses, wherein the one or more analyses comprises at least one of
one or more temporal analyses comprising at least one of
an intra-temporal analysis, and
an inter-temporal analysis; and
one or more inter-resident analysis.

15. The system of claim 14, wherein one or more interfaces presented by the energy consumption application is used to obtain the one or more analyses.

16. The system of claim 12, wherein the enterprise energy consumption application is used to perform at least one of
a temporal analysis,
an inter-property analysis, and
an intra-property analysis.
